(19) United States
(12) Patent Application Publication
(10) Pub. No.: US 2007/0218283 A1
(43) Pub. Date: Sep. 20, 2007

(54) Method of Producing Carbon-Encapsulated Metal Nanoparticles

(75) Inventors: Junfeng Geng, Cambridge (GB); Brian F.G. Johnson, Cambridge (GB)

Correspondence Address: PILLSBURY WINTHROP SHAW PITTMAN, LLP, P.O. BOX 10500, MCLEAN, VA, 22102, US

(73) Assignee: Cambridge Enterprise Limited The Old Schools, Cambridge (GB)

(21) Appl. No.: 10/587,216

(22) PCT Filed: Jan. 26, 2005
(86) PCT No.: PCT/GB05/00279

§ 371 Date: May 29, 2007

(30) Foreign Application Priority Data
Jan. 26, 2004 (GB) 0401644.0

(51) Int. Cl. C23C 16/00

(52) U.S. Cl. 428/403; 427/216

(57) ABSTRACT

A method of producing carbon-encapsulated metal nanoparticles, for example carbon-encapsulated magnetic metal nanoparticles, including providing a carbon-containing metal salt or organometallic compound in a reactor, for example a vessel having a restricted opening and decomposing the carbon-containing metal salt or organometallic compound, for example by heating, whilst maintaining carbon within the reactor to form carbon-encapsulated metal nanoparticles.

The present invention relates to a method of producing carbon-encapsulated metal nanoparticles.

Carbon-encapsulated magnetic nanoparticles are important new nanomaterials (Peter J. Harris, Chapter 5, “Carbon Nanotubes and Related Structures”, Cambridge University Press, 1999). The carbon-encapsulated magnetic nanoparticles consist of magnetic nanoparticles (for example of iron, nickel or cobalt) encapsulated within carbon nanotubes or fullerene-like or polyhedral graphitic cages. In either case, a completely sealed carbon structure is typically found. The typical particle size is 10 to 500 nm.

Applications of carbon-encapsulated magnetic nanoparticles include high-density magnetic data storage, magnetic toners for use in photocopiers, magnetic inks and ferrofluids (S. Subramoney, Adv. Mater. 10, 1 557, 1998). The carbon coatings mean that the magnetic nanoparticles are biocompatible and are stable in many organic media. Thus, carbon-encapsulated magnetic nanoparticles are candidates for bioengineering applications, for example drug delivery, biosensors, magnetic hyperthermia and magnetic contrast agents for Magnetic Resonance Imaging (A. A. Bogdanov, C. Martin, R. Weissleder, T. J. Brady, Biochim. Biophys. Acta, 1193, 212, 1994).

Because of the protective graphitic sheets encapsulating the magnetic nanoparticles, the magnetic nanoparticles are protected from the environment and from degradation. In addition, the graphitic sheets isolate the magnetic nanoparticles magnetically from one another. This means that problems caused by interaction between closely spaced magnetic bits are avoided.

Carbon-encapsulated magnetic nanoparticles have been produced by arc evaporation in the Huffman-Kratschmer chamber (T. Hayashi, S. Hirono, M. Tomita, S. Umemura, Nature, 381, 772, 1996; J. Henry, J. Scott and S. A. Majetich, Phys. Rev. B, 52, No. 17, 12564, 1995). This technique involves evaporation of a mixture of metal catalyst and graphite by electrical arc discharge (typically 100-200 A) at extremely high temperatures (above 3000° C.).

Laser ablation has also been used. This method produces carbon-encapsulated magnetic nanoparticles in a much higher yield than arc discharge. However, although both methods can produce good quality products, they are unsuitable for use on a large scale because of poor and irreproducible yields and presence of many carbonaceous by-products.

Carbon-encapsulated magnetic nanoparticles have been produced by Chemical Vapour Deposition (CVD) by passing a carbon source (typically a hydrocarbon) over a supported metal catalyst. This method is low-cost and only requires simple apparatus, and can be well controlled. However, this method cannot be used to produce carbon-encapsulated magnetic nanoparticles on a large scale because of poor yields and the difficulty of separating the carbon-encapsulated magnetic nanoparticles from the supporting materials (Z. Y. Zhong, H. Y. Chen, S. B. Tang, J. Ding, J. Y. Lin, K. L. Tan, Chem. Phys. Lett., 330, 47, 2000).

Carbon-encapsulated magnetic nanoparticles have also been produced by pyrolysis of non-graphitising carbon (P. J. F. Harris and S. C. Tsang, Chem. Phys. Lett., 293, 53, 1998). The non-graphitising carbon is first impregnated with a salt of the metal to be encapsulated. The dried product is heated to temperatures of 1800 to 2500° C. The encapsulated products are similar to those prepared by the arc discharge method. However, the yield of product is low.

The present inventors have invented a new method suitable for large scale synthesis of carbon-encapsulated magnetic nanoparticles.

Accordingly, in a first aspect, the present invention provides a method of producing carbon-encapsulated metal nanoparticles, comprising the steps of:
providing a carbon-containing metal salt or organometallic compound in a reactor; and
decomposing the carbon-containing metal salt or organometallic compound to form carbon-encapsulated metal nanoparticles.

Preferably, carbon is maintained within the reactor during decomposition. The carbon may be in elemental or molecular form. Carbon should be maintained at a vapour pressure at the reaction site adequate to ensure that carbon-encapsulated metal nanoparticles are formed. It is not necessary for all carbon contained in the metal salt or organometallic compound to be maintained within the reactor.

Preferably, decomposition is carried out in a reactor having a restricted opening. The reactor thus substantially confines the carbon within the reactor where it reacts to form carbon-encapsulated metal nanoparticles. It is preferred to provide a restricted opening so that by-products of decomposition can escape from the reactor.

Preferably, the reactor is a tube having one sealed end and one end with a restricted opening. The tube should have a large length to diameter ratio, for example a ratio of 30 or higher. This also assists in confining carbon within the reactor. Alternatively, the reactor may be a flask having a restricted opening.

Preferably, a means of escape for elements other than carbon and metal released during decomposition (e.g. oxygen and nitrogen) is provided. Suitably, a gas flow to carry away such elements is provided.

However, a unidirectional gas flow across the reaction site is preferably prevented. This assists in preventing carbon from being carried away from the reaction site. Where a flow of gas is provided during reaction, the flow should be directed towards the restricted opening of the reactor.

Preferably, the carbon-containing metal salt is decomposed under an inert gas atmosphere. This prevents formation of metal oxides and carbon dioxide. Preferably, a flow of inert gas is provided.

Suitably, the inert gas is argon. If nitrogen is used as an inert gas, some incorporation of nitrogen into the product may be found.

Preferably, the carbon-containing metal salt is decomposed by heating. Alternatively, the salt may be decomposed by irradiation.

Preferably, heating is carried out at a temperature of 700 to 1500° C. More preferably, heating is carried out at a temperature of 700 to 1200° C. A temperature below 700° C. favours the formation of amorphous carbon. A temperature above 1500° C. leads to rapid decomposition which may result in agglomeration of the metal to form large chunks. Such chunks are not normally catalytically active.

Preferably, the metal is iron, nickel, cobalt, ruthenium, osmium, rhodium, iridium, palladium, platinum, a lanthanide or uranium. More preferably, the metal is a magnetic metal.

Preferably, the carbon-containing metal salt or organometallic compound contains at least 5 carbon atoms per metal atom.

Preferably, the carbon-containing metal salt is a carboxylic acid metal salt. Suitably, the carbon-containing metal salt is a stearate.

In a second aspect, the present invention relates to carbon-encapsulated metal nanoparticles produced by a method as described above.

The invention will be further described with reference to the Examples and as illustrated in the Figures, in which:

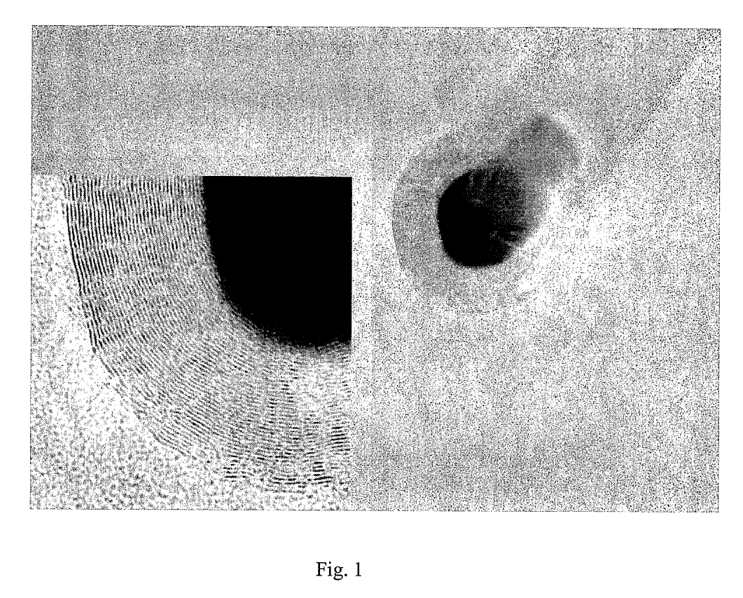

FIG. 1 shows a TEM image of an encapsulated nanoparticle produced in Example 1.

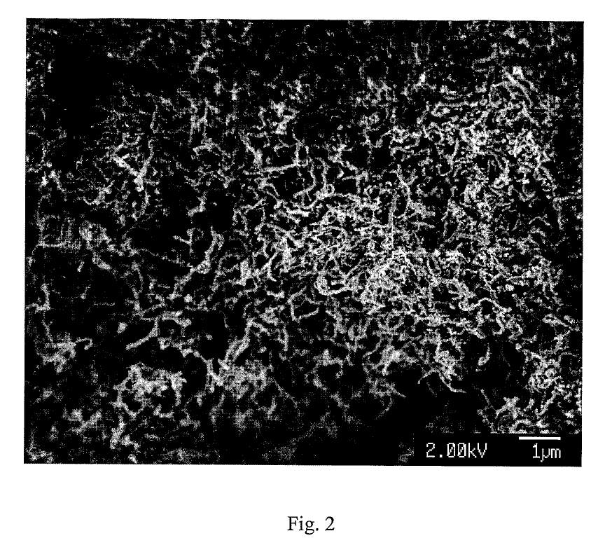

FIG. 2 shows an SEM image of the carbon nanotubes produced in Example 1.

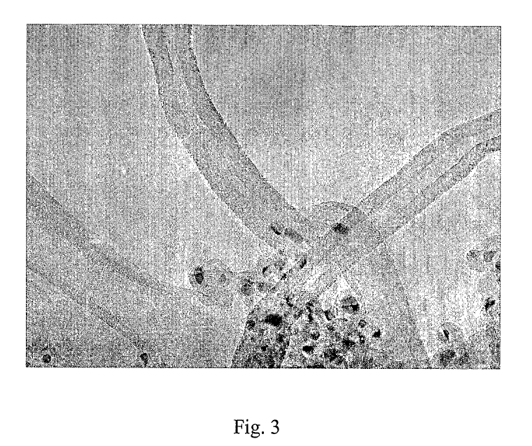

FIG. 3 shows a TEM image of two carbon nanotubes produced in Example 1.

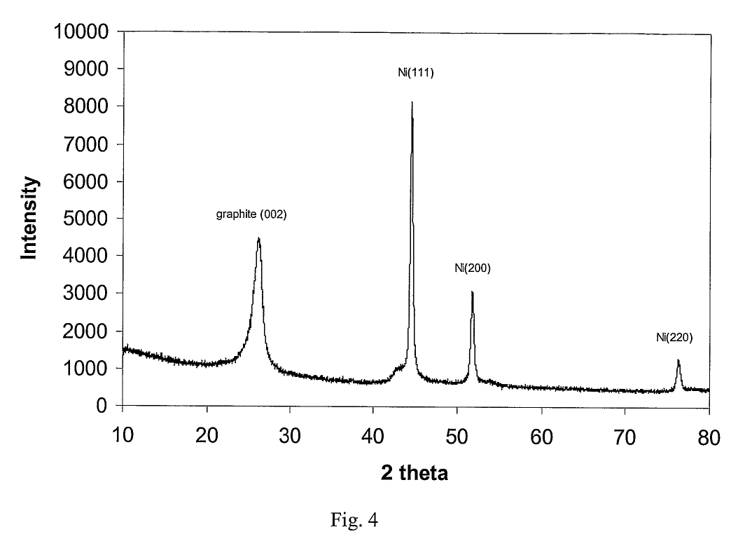

FIG. 4 shows an X-ray diffraction profile of the product of Example 1.

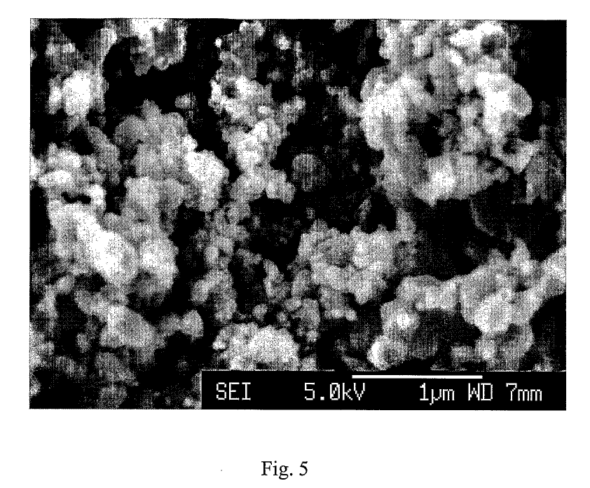

FIG. 5 shows an SEM image of encapsulated iron nanoparticles produced in Example 4.

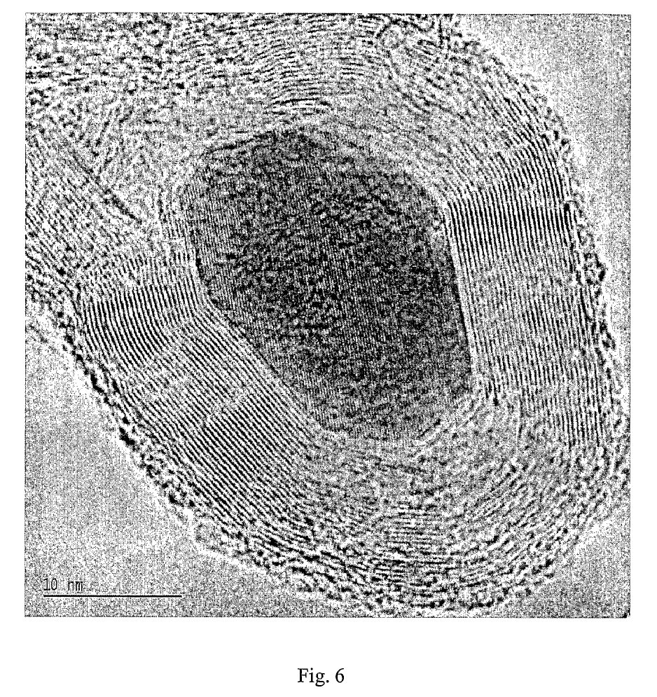

FIG. 6 shows a TEM image of an encapsulated Fe₃C nanoparticle produced in Example 4.

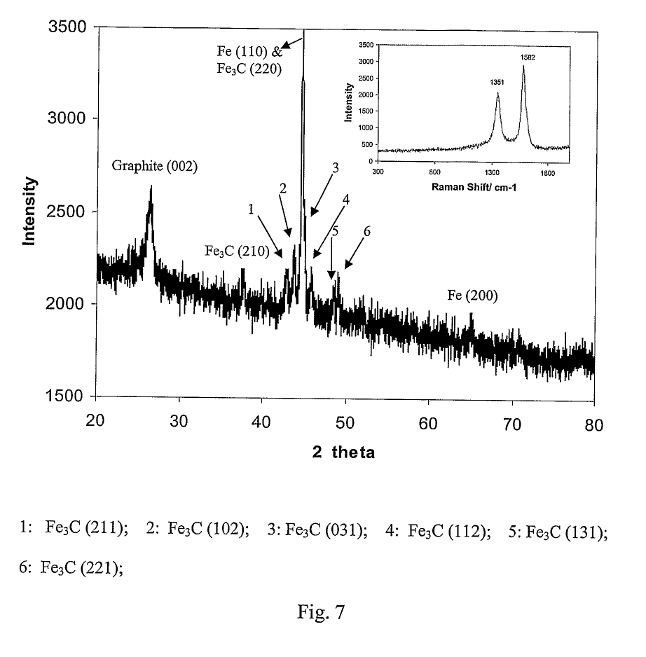

FIG. 7 shows X-ray diffraction and Raman spectra of the product of Example 4.

### EXAMPLE 1

Nickel stearate (about 1.5 g, fine green powder) was evenly distributed in a quartz reactor having the shape of a tube of length 500 mm and diameter 11 mm with a first sealed end and a second end with a small opening of diameter 4 mm. The reactor was pumped to vacuum and filled with argon. The reactor was slowly introduced into a tubular furnace of length 800 mm and diameter 40 mm. The furnace was preheated to 800 ° C. and a flow of argon (1 to 2 l/min) was passed through the furnace. The small opening of the reactor was directed towards the flow of argon. The reactor was heated in the furnace for 10 mins and the furnace was then cooled to room temperature. The produced was collected at room temperature.

During loading of the reactor into the furnace the nickel stearate changed from green to black in colour. Some gas passed out of the reactor during heating. The product (a fine black powder) was examined by SEM and TEM and was found to consist of carbon nanotubes and carbon-encapsulated nickel nanoparticles in fullerene-like or polyhedral graphite cages.

The carbon encapsulated nickel nanoparticles (FIG. 1) were found to have a typical diameter of 30 to 150 nm. The graphite layers were well crystallised with 10 to 50 layers.

The carbon nanotubes (FIG. 2) were found to have a typical internal diameter of 10 to 30 nm, although some much finer tubes of diameter less than 5 nm and larger tubes of diameter larger than 50 nm were also observed. TEM observations (FIG. 3) indicated that most nanotubes were multi-walled with 10 or more graphene layers. Many nanotubes also had nickel nanoparticles encapsulated inside.

No naked nickel nanoparticles were observed under intensive and repeated microscope observations, indicating that substantially all the nickel nanoparticles produced were encapsulated either in the fullerene-like or polyhedral graphitic cages or in carbon nanotubes. The yield of encapsulated nickel product was thus approximately 100%.

Electron diffraction and X-ray tests (FIG. 4) confirmed that the encapsulated nickel nanoparticles were pure nickel nanocrystals and that the surrounding carbon was well crystallined graphite.

Elemental analysis indicated C: 74% (corresponding to Ni: 26%).

### EXAMPLE 2

The method of Example 1 was repeated at 1000° C. Examination of the products by electron microscopy indicated that they were similar in structure to the products of Example 1, but that the graphite layers were even better crystallined. This indicates further that a higher temperature increases the degree of graphitisation.

### EXAMPLE 3

The stability of the products of Example 1 was tested by heating a sample in air to 400° C. in a quartz vial and cooling it to room temperature over 12 hours. No weight loss or colour change was observed. This indicates that the products had good thermal stability and that there was no amorphous carbon in the products, since this would have burnt at a temperature of 355 to 400° C. to give a weight loss of the sample. It also indicates that there were no naked nickel particles in the sample since these would have been oxidised. The good stability is also confirmed that no degradation has so far been observed for product exposed to air for over 10 months.

### EXAMPLE 4

The method of Example 1 was repeated using iron stearate rather than nickel stearate. The iron stearate was ground using a pestle and mortar. It was found that only carbon-encapsulated iron nanoparticles were produced (FIGS. 5 and 6). No naked iron nanoparticles were produced. The product contained a small proportion of carbon nanotubes (estimated by SEM as less than 1%).

X-ray examination (FIG. 7) indicated that the encapsulated species were pure iron nanocrystals and iron carbide (Fe₃C) nanocrystals. The yield of encapsulated product was thus approximately 100%.

### EXAMPLE 5

The method of Example 1 was repeated using cobalt citrate rather than nickel stearate. The product was a mixture of carbon-encapsulated cobalt nanoparticles and naked cobalt particles.

### COMPARATIVE EXAMPLE 1

Nickel stearate was heated to 800° C. in a boat under argon atmosphere. Naked nickel particles were produced.

### COMPARATIVE EXAMPLE 2

Example 1 was repeated using a reactor having the shape of a tube of length 500 mm and diameter 11 mm with both ends open. Naked nickel particles were produced.

The high yields of encapsulated product achieved in the Examples mean that these methods are suitable for bulk synthesis of carbon-encapsulated magnetic nanoparticles and carbon nanotubes.

The method of the Examples does not produce naked metal nanoparticles which are typical by-products in arc discharge. Further, the temperatures used in the Examples are much lower than those required for arc discharge. The apparatus used in the Examples is also much simpler than the arc discharge chamber.

The method of the Examples gives a much higher yield than the non-graphitising carbon method. Again, the temperatures used in the Examples are much lower than those required for the non-graphitising carbon method.

The method of the Examples does not require the separate carbon source, catalyst and supporting materials of the CVD method. Instead, the stearate salt provides these three functions.

Comparison of the Examples and Comparative Examples show that to achieve good results argon must not be allowed to flow freely over the metal salt. It is believed that confinement of atomic carbon near the reaction zone is necessary for formation of the desired product. Use of a long tubular reactor also assists in confining carbon. The reactor used in the Examples has a length to diameter ratio of about 46.

Whilst the applicants do not wish to be bound by this theory, they believe that the large carbon to metal ratio of nickel stearate contributes to the good results achieved in the Examples.

In nickel stearate, the metal content is 9.4 wt % and the carbon content is 66 wt %. The metal content falls within the typical metal loading range for heterogeneous catalysts (5 to 10%). In contrast to a heterogeneous catalyst, nickel stearate provides a medium in which the dispersion of nickel atoms is uniform at a molecular level.

Although the apparent ratio of carbon to nickel is 36 to 1, the inventors believe that the effective ratio is much higher. This is because as nickel atoms are formed by thermal decomposition of the salt they readily agglomerate to give particles, and only the nickel atoms on the particle surface are catalytically active. For example, a spherical nickel particle with a diameter of 20 nm contains about 6.4×10⁵ atoms of which only about 3.7% are on the surface. This increases the effective carbon to nickel ratio to about 1000 to 1. The ratio increases as the particle size increases.

The inventors believe that the high ratio of carbon to nickel within nickel stearate means that under appropriate conditions thermal decomposition of the molecule will produce nickel nanoparticles as catalytic seed and sufficient carbon atoms to provide feedstock for the growth of carbon nanostructures.

1. A method of producing carbon-encapsulated metal nanoparticles, comprising:
providing a carbon-containing metal salt or organometallic compound in a reactor; and
decomposing the carbon-containing metal salt or organometallic compound whilst maintaining carbon within the reactor to form carbon-encapsulated metal nanoparticles.

2. A method as claimed in claim 1, wherein the reactor is a vessel having a restricted opening.

3. A method as claimed in claim 2, wherein the vessel is a tube having one sealed end and one end with a restricted opening.

4. A method as claimed in claim 1, wherein a unidirectional gas flow across the reaction site is prevented.

5. A method as claimed in claim 1, wherein the carbon-containing metal salt or organometallic compound is decomposed under an inert gas atmosphere.

6. A method as claimed in claim 5, wherein the inert gas is argon.

7. A method as claimed claim 1, wherein the carbon-containing metal salt is decomposed by heating.

8. A method as claimed in claim 7, wherein heating is carried out at a temperature of 700 to 1500° C.

9. A method as claimed in claim 1, wherein the metal is iron, nickel, cobalt, ruthenium, osmium, rhodium, iridium, palladium, platinum, a lanthanide or uranium.

10. A method as claimed in claim 9, wherein the metal is a magnetic metal.

11. A method as claimed in claim 1, wherein the carbon-containing metal salt or organometallic compound contains at least 5 carbon atoms per metal atom.

12. A method as claimed in claim 1, wherein the carbon-containing metal salt is a carboxylic acid metal salt.

13. A method as claimed in claim 12, wherein the carbon-containing metal salt is a stearate or a citrate.

14. Carbon-encapsulated metal nanoparticles produced by a method as claimed in claim 1.
